(19) United States
(12) Patent Application Publication
(10) Pub. No.: US 2010/0009521 A1
(43) Pub. Date: Jan. 14, 2010

(54) METHOD OF PRODUCING SEMICONDUCTOR WAFER

(75) Inventors: Takaaki Shiota, Tokyo (JP); Wataru Itou, Tokyo (JP); Takashi Nakayama, Tokyo (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: Sumco Corporation, Tokyo (JP)

(21) Appl. No.: 12/501,331

(22) Filed: Jul. 10, 2009

(30) Foreign Application Priority Data
Jul. 11, 2008 (JP) 2008-181081

(51) Int. Cl. H01L 21/322

(52) U.S. Cl. 438/473; 257/E21.318

(57) ABSTRACT

There is provided a production method in which the beveling step conducted for preventing the cracking or chipping in a raw wafer during the grinding can be omitted when the raw wafer cut out from a crystalline ingot is processed into a double-side mirror-finished semiconductor wafer and a semiconductor wafer can be obtained cheaply by shortening the whole of the production steps for the semiconductor wafer and decreasing the machining allowance of silicon material in the semiconductor wafer to reduce the kerf loss of the semiconductor material as compared with the conventional method.

The method is characterized by comprising a slicing step of cutting out a thin disc-shaped raw wafer from a crystalline ingot; a fixed grain bonded abrasive grinding step of sandwiching the raw wafer between a pair of upper and lower platens each having a pad of fixed grain bonded abrasive to simultaneously grind both surfaces of the raw wafer; a heat treating step of subjecting the raw wafer to a given heat treatment after the fixed grain bonded abrasive grinding step; and a one-side polishing step of polishing each of the both surfaces of the raw wafer after the heat treating step.

### BACKGROUND OF THE INVENTION

1. Field of the Invention

This invention relates to a method of producing a semiconductor wafer and, more particularly to a method of producing a double-side mirror-finished semiconductor wafer by cutting out a thin disc-shaped raw wafer from a crystalline ingot.

2. Description of the Related Art

In general, the conventional method of producing a semiconductor wafer comprises sequentially-conducted steps of (Slicing step)→(First beveling step)→(Lapping step)→(Second beveling step)→(One-side grinding step)→(Double-side polishing step)→(One-side finish polishing step)→(Heat treatment).

In the slicing step, a thin disc-shaped raw wafer is cut out from a crystalline ingot by cutting. In the first beveling step, an outer peripheral portion of the cut raw wafer is beveled so as to suppress chipping or cracking of the raw wafer in the subsequent lapping step. In the lapping step, the beveled raw wafer is lapped, for example, with a grinding stone of #1000 to improve a flatness of the raw wafer. In the second beveling step, an outer peripheral portion of the lapped raw wafer is beveled to render the end face of the raw wafer into a given beveled shape. In the one-side grinding step, one-side surface of the beveled raw wafer is ground, for example, with a grinding stone of #2000 to #8000 to approximate the thickness of the raw wafer to a final thickness. In the double-side polishing step, both surfaces of the one-side ground raw wafer are polished. In the one-side finish polishing step, one-side surface as a device face of the double-side polished raw wafer is further subjected to a finish polishing. Lastly, the heat treatment is carried out for improving the surface quality such as reduction of crystal defects, formation of oxygen precipitates and the like.

The above-mentioned conventional method is a method for producing a double-side mirror-finished semiconductor wafer through the two beveling steps, lapping step and one-side grinding step, so that the number of steps is large and there is a problem that kerf loss of a semiconductor material (loss of a semiconductor material due to increase of lapping debris and one-side grinding debris) is caused. Further, since the heat treatment is conducted lastly, there is a problem that strains generated in a semiconductor wafer by the heat treatment lead to cause cracking, chipping and the like through vibrations or impacts during the transportation or in the production of a semiconductor device.

Particularly, the above problem is remarkable in a large-size semiconductor wafer such as a silicon wafer having a diameter of not less than 450 mm. For example, when a large-size silicon wafer having a diameter of 450 mm is produced with a machining allowance of the same silicon material as in the presently mainstream silicon wafer having a diameter of 300 mm, the kerf loss of the silicon wafer becomes 2.25 times and the in-plane thermal stress becomes 1.5 times.

Furthermore, when the aforementioned lapping step is included in the production method of a silicon wafer having a diameter of not less than 450 mm, there is a fear that the lapping apparatus significantly grows in size and problems occur with respect to installation site of the lapping apparatus or the like in the formulation of a production line.

In Patent Document 1 is proposed a method of producing a semiconductor wafer wherein a double-side grinding step is used instead of the lapping step in the above conventional method.

Patent Document 1: Japanese Patent No. 3328193

The method of producing a semiconductor wafer as disclosed in Patent Document 1 solves the problem that the lapping apparatus grows in size in the production of large-size semiconductor wafers and has an advantage that the first beveling step before the double-side grinding step can be omitted, but it is unchanged that the machining allowance of the silicon material is large due to the passing through the double-side grinding step and the one-side grinding step, and hence there still remains a problem in the kerf loss.

Also, it is expected to improve the flatness of the semiconductor wafer, which will be predicted to satisfy severer request in future, by reducing the machining allowance of the semiconductor wafer.

Furthermore, as thermal stress is increased with the increase of the diameter in the large-size wafer, there is a problem that strains generated in the heat treatment lead to cause cracking, chipping and the like through vibrations or impacts during the transportation or in the production of a semiconductor device.

### SUMMARY OF THE INVENTION

With the foregoing in mind, it is an object of the invention to provide a production method, in which the beveling step conducted for preventing the cracking or chipping in a raw wafer during the grinding can be omitted when the raw wafer cut out from a crystalline ingot is processed into a double-side mirror-finished semiconductor wafer and the semiconductor wafer can be obtained cheaply by reducing the production step number for the semiconductor wafer and further decreasing the machining allowance of silicon material in the semiconductor wafer to reduce the kerf loss of the semiconductor material.

Particularly, the invention exerts a remarkable effect when the semiconductor wafer is a large-size silicon wafer having a diameter of not less than 450 mm.

In order to solve the above problems, the inventors have made various studies on a step capable of grinding a raw wafer cut out from a crystalline ingot without beveling an end face thereof and a chemical treating step capable of removing machining strain from the semiconductor wafer after the grinding and simultaneously beveling the end face.

As a result, it has been found that the number of steps but also the machining allowance of the semiconductor wafer can be reduced as compared with the conventional method by conducting a fixed grain bonded abrasive grinding step, which allows simultaneous grinding of both surfaces from rough grinding to finish grinding at once, instead of the lapping step and the one-side grinding step in the above conventional method together with a chemical treating step capable of removing machining strains from the surfaces and end faces of the semiconductor wafer and simultaneously conducting the beveling.

The invention is based on the above knowledge, and the summary and construction thereof are as follows.

(1) A method of producing a semiconductor wafer, which comprises a slicing step of cutting out a thin disc-shaped raw wafer from a crystalline ingot; a fixed grain bonded abrasive grinding step of sandwiching the raw wafer between a pair of upper and lower platens each having a pad of fixed grain bonded abrasive to simultaneously grind both surfaces of the raw wafer; a heat treating step of subjecting the raw wafer to a given heat treatment after the fixed grain bonded abrasive grinding step; and a one-side polishing step of polishing each of the both surfaces of the raw wafer after the heat treating step.

(2) A method of producing a semiconductor wafer, which comprises a slicing step of cutting out a thin disc-shaped raw wafer from a crystalline ingot; a fixed grain bonded abrasive grinding step wherein the raw wafer is fitted into a circular hole of a carrier having a plurality of circular holes closely aligned to each other and thereafter the carrier is sandwiched between a pair of upper and lower platens each having a pad of fixed grain bonded abrasive and then the upper and lower platens are rotated while oscillating the carrier in the same horizontal plane to simultaneously conduct a high-speed treatment from rough grinding to finish grinding on both surfaces of the raw wafer at once; a heat treating step of subjecting the raw wafer worked at the high speed in the fixed grain bonded abrasive grinding step to a given heat treatment; a chemical treating step of simultaneously conducting mitigation of machining strains from the surfaces and end face of the raw wafer subjected to the heat treatment and finish beveling of the end face of the raw wafer into a given beveled shape; and a one-side finish polishing step of finish-polishing the surface of the chemical-treated raw wafer.

(3) A method of producing a semiconductor wafer according to the item (1) or (2), wherein the given heat treatment includes a high-temperature defect-shrinking and elimination heat treatment for vanishing defects from a surface layer of the raw wafer at a higher temperature and/or an IG heat treatment for forming a gettering layer or a vacancy injected layer as a nucleus thereof in an interior of the raw wafer other than the surface layer thereof.

(4) A method of producing a semiconductor wafer according to the item (3), wherein the IG heat treatment includes a heat treatment at a middle temperature range of 700 to 900° C. for not less than 30 minutes for forming precipitation nuclei or a heat treatment in a high-temperature nitriding atmosphere of not lower than 1150° C. for vacancy injection.

(5) A method of producing a semiconductor wafer according to the item (3) or (4), wherein the high-temperature defect-shrinking and elimination heat treatment includes a heat treatment in an atmosphere of a reducing gas, an inert gas or a mixed gas thereof at 1100 to 1350° C. for not less than 1 minute.

(6) A method of producing a semiconductor wafer according to any one of the items (1) to (5), wherein the semiconductor wafer is a large-size silicon wafer having a diameter of not less than 450 mm.

In the method of producing a semiconductor wafer according to the invention, the fixed grain bonded abrasive grinding step, the heat treating step and the one-side polishing step are conducted after the slicing step, which is linked to shorten the whole of the production steps of the semiconductor wafer as compared with the conventional method and significantly reduces the machining allowance of the semiconductor wafer to reduce the kerf loss of the semiconductor material, whereby it is made possible to obtain a semiconductor wafer cheaply.

Also, the flatness of the semiconductor wafer can be improved by reducing the machining allowance of the semiconductor wafer.

Furthermore, by conducting the chemical treating step after the heat treating step to remove machining strains of the semiconductor wafer after the grinding or strains in the heat treatment and at the same time conduct the beveling of the end face can be removed edge damages in the heat treatment.

In addition, it is possible to change the semiconductor wafer into a semiconductor wafer having an epitaxial layer by conducting an epitaxial layer growing step after the chemical treating step or the one-side polishing step.

In particular, the method of producing a semiconductor wafer according to the invention is suitable in the production of a large-size silicon wafer having a diameter of not less than 450 mm.

### BRIEF DESCRIPTION OF THE DRAWING

The invention will be described in detail with reference to the accompanying drawings, wherein

FIG. 1 is a flow chart illustrating a first embodiment of the invention;

FIG. 2 is a diagrammatical view schematically showing a fixed grain bonded abrasive grinding apparatus used in a fixed grain bonded abrasive grinding step, wherein (a) is a vertically cross-sectional view of the apparatus used in the fixed grain bonded abrasive grinding step, (b) is a schematic top view in a horizontal direction showing a state just before the start of the fixed grain bonded abrasive grinding step and (c) is a schematic top view in a horizontal direction showing a state after a predetermined time of the fixed grain bonded abrasive grinding step;

FIG. 3 is a diagrammatical view schematically showing an apparatus used in a lapping step conducted in the conventional method;

FIG. 4 is a flow chart illustrating a production method of Comparative Example 1; and

FIG. 5 is a flow chart illustrating a production method of Comparative Example 2.

### DESCRIPTION OF REFERENCE SYMBOLS

10 fixed grain bonded abrasive grinding apparatus
11a, 11b, 11c circular hole
12 carrier
13a, 13b pad of fixed grain bonded abrasive
14, 14a, 14b platen
15a, 15b, 15c, 15d guide roller
16a, 16b, 16c semiconductor wafer
50 lapping apparatus
51a, 51b, 51c, 51d, 51e circular hole
52a, 52b, 52c, 52d, 52e carrier
53a, 53b pad
54, 54a, 54b platen
55 outer peripheral gear
56 center gear
57a, 57b, 57c, 57d, 57e semiconductor wafer

### DESCRIPTION OF THE PREFERRED EMBODIMENTS

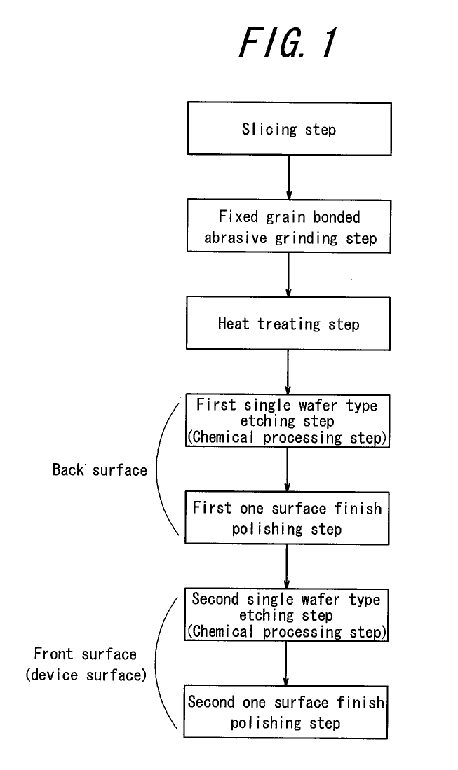

FIG. 1 is a flow chart illustrating a typical embodiment of the invention. In the embodiment, the following four steps are conducted in the order from (1) to (4):

(1) Slicing step of cutting out a thin disc-shaped raw wafer from a crystalline ingot;

(2) Fixed grain bonded abrasive grinding step wherein the raw wafer is fitted into a circular hole of a carrier having a plurality of circular holes closely aligned to each other and then the carrier is sandwiched between a pair of upper and lower platens each having a pad of fixed grain bonded abrasive and then the upper and lower platens are rotated while oscillating the carrier in the same horizontal plane to simultaneously conduct a high-speed treatment from rough grinding to finish grinding on both surfaces of the semiconductor wafer at once

(3) Heat treating step of subjecting the semiconductor wafer to a heat treatment after the fixed grain bonded abrasive grinding step

(4) Chemical treating step of simultaneously conducting mitigation of machining strains from the surfaces and end face of the semiconductor wafer and finish beveling of the end face of the semiconductor wafer into a given beveled shape after the heat treating step, and One-side finish polishing step of finish-polishing the chemical-treated surface of the semiconductor wafer after the chemical treating step

Each step in the embodiment of the invention will be explained below.

(Slicing Step)

The slicing step is a step wherein a thin disc-shaped wafer is cut out by contacting and cutting a crystalline ingot with a wire saw while feeding a grinding solution or by cutting a crystalline ingot with a circular periphery blade. In order to reduce a processing load in the subsequent fixed grain bonded abrasive grinding step or chemical treating step, the semiconductor wafer after the slicing step is preferable to have a high flatness and a small surface roughness as far as possible.

Moreover, the crystalline ingot is typically a silicon single crystal ingot, but may be a silicon polycrystalline ingot for solar cells.

(Fixed Grain Bonded Abrasive Grinding Step)

The fixed grain bonded abrasive grinding step is a step wherein both surfaces of the semiconductor wafer cut out at the slicing step are roughly ground to improve the flatness of the wafer and to approximate the thickness of the semiconductor wafer to a final thickness.

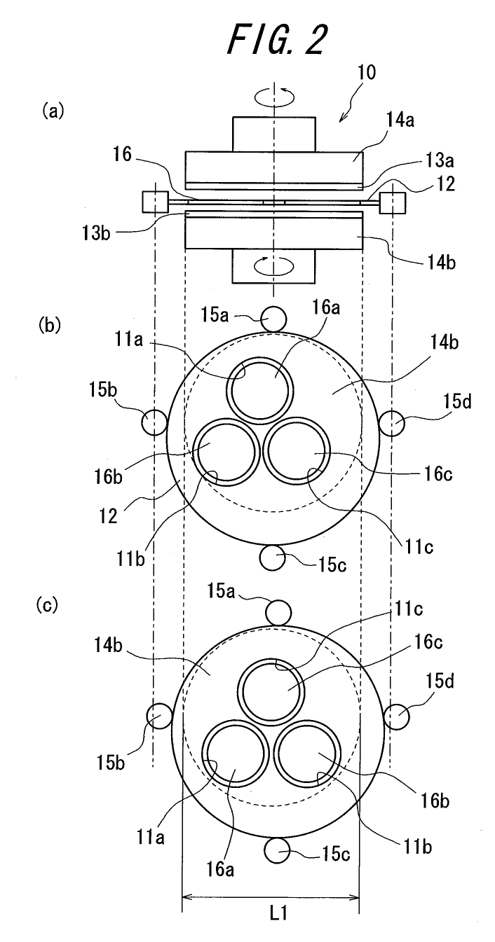

FIG. 2 is a diagrammatical view schematically showing a fixed grain bonded abrasive grinding apparatus 10 used in the fixed grain bonded abrasive grinding step. FIG. 2(a) among FIGS. 2(a) to (c) is a vertically cross-sectional view of the fixed grain bonded abrasive grinding apparatus 10 used in the fixed grain bonded abrasive grinding step, and FIGS. 2(b) and 2(c) are schematically top views of the fixed grain bonded abrasive grinding apparatus 10 used in the fixed grain bonded abrasive grinding step at a state of taking off an upper platen. Also, FIGS. 2(a) and 2(b) among FIGS. 2(a) to (c) are schematic views showing states just before the start of the fixed grain bonded abrasive grinding step, and FIG. 2(c) is a schematic view showing a state after a certain time of the fixed grain bonded abrasive grinding step.

The fixed grain bonded abrasive grinding apparatus 10 comprises a carrier 12 having a plurality of circular holes 11a, 11b and 11c closely aligned to each other, pads 13a, 13b each having a fixed grain bonded abrasive, a pair of upper and lower platens 14a and 14b having the pads 13a and 13b, and guide rollers 15a, 15b, 15c and 15d arranged so as to contact with a side face of the carrier 12 at four divided positions of the circumference of the carrier 12.

The semiconductor wafers 16a, 16b and 16c cut out in the slicing step are fitted into the circular holes 11a, 11b and 11c of the carrier 12, and then the carrier 12 is sandwiched between the pair of upper and lower platens 14a and 14b having the pads 13a and 13b with the fixed grain bonded abrasive, and then the upper and lower platens 14a and 14b are rotated while moving the guide rollers 15a, 15b, 15c and 15d to oscillate the carrier 12 in the same horizontal plane, whereby both surfaces of the wafers 16a, 16b and 16c are ground simultaneously.

Although there are shown three circular holes of 11a, 11b and 11c in FIG. 2, the number of circular holes is not limited to three, and can be increased or decreased, if necessary. However, as shown in FIGS. 2(b) and 2(c), it is important that all of the circular holes 11a, 11b and 11c are disposed so as to enter into the circumference of the upper and lower platens 14a and 14b even if the carrier 12 takes any positional relationship with respect to the upper and lower platens 14a and 14b through oscillating. This is due to the fact that a pressure applied to the semiconductor wafer during the fixed grain bonded abrasive grinding is made uniform as far as possible, whereby the occurrence of cracking or chipping in the semiconductor wafer during the fixed grain bonded abrasive grinding is prevented but also the flatness of the semiconductor wafer after the fixed grain bonded abrasive grinding is improved without beveling an outer peripheral portion of the semiconductor wafer after the slicing step. It is preferable that the circular holes 11 have the same diameter and the number thereof is 3, because as shown in FIGS. 2(b) and 2(c), if the circular holes 11a, 11b and 11c are aligned closely to each other, the diameter of the platen 14 can be made minimum and the size of the fixed grain bonded abrasive grinding apparatus 10 is not unnecessarily grown.

Moreover, when the diameter of the platen 14 is L1 in FIG. 2, if three silicon wafers each having a diameter of 450 mm are ground with the fixed grain bonded abrasive, L1 is about 985 mm.

Since the pads 13a and 13b have fixed grain bonded abrasives, it is not required to supply a slurry of free abrasive grains during the fixed grain bonded abrasive grinding. Therefore, it is possible to avoid the deterioration of the flatness of the semiconductor wafer after the grinding due to non-uniform supply of the free abrasive grains, which is advantageous especially in a case that a diameter of the semiconductor wafer is large as in a silicon wafer having a diameter of not less than 450 mm and it is difficult to supply the free abrasive grains uniformly.

The material of the abrasive grains in the pad having the fixed grain bonded abrasive is preferable to be diamond, but abrasive grains of SiC may be also used. Although the pad with the fixed grain bonded abrasive may have a roughness of #1000˜8000, as previously mentioned, the pressure applied to the semiconductor wafer during the fixed grain bonded abrasive grinding is uniform and the grinding action of the abrasive grains to the semiconductor wafer is uniform owing to the use of the fixed grain bonded abrasive instead of the free abrasive grains, so that it is possible to conduct a high-speed treatment from rough grinding to finish grinding at once without the occurrence of cracking or chipping even if a semiconductor wafer having a rough sliced surface state just after the slicing step is subjected to a fixed grain bonded abrasive grinding with a fine pad of about #8000.

During the fixed grain bonded abrasive grinding, it is preferable to wash out grinding debris, or to supply water or an alkali solution for the purpose of lubrication.

Moreover, when a grinding margin at the fixed grain bonded abrasive grinding step is less than 20 μm per one-side surface, the undulation of the wafer generated in the slicing will be a problem, while when it exceeds 50 μm, the strength of the wafer becomes lacking. Therefore, the grinding margin at the fixed grain bonded abrasive grinding step is preferable to be 20-50 μm per one-side surface.

Now, the lapping step will be briefly described to compare the fixed grain bonded abrasive grinding step employed in the invention with the lapping step employed in the conventional method.

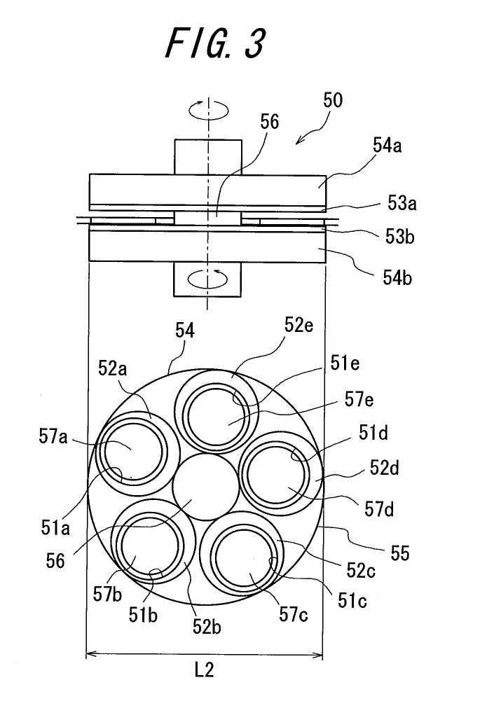

In FIG. 3 is schematically shown an apparatus used in the lapping step employed in the conventional method. The lapping apparatus 50 comprises carriers 52a, 52b, 52c, 52d, 52e each having a respective circular hole 51a, 51b, 51c, 51d, or 51e and provided on its side face with a gear, pads 53a, 53b, a pair of upper and lower platens 54a, 54b having the pads 53a, 53b, an outer peripheral guide 55 in the sun-and-planet motion of the carriers 52a, 52b, 52c, 52d, 52e, and a center gear 56 engaging with the gears provided on the side faces of the carriers 52a, 52b, 52c, 52d, 52e.

The semiconductor wafers 57a, 57b, 57c, 57d, 57e cut out in the slicing step are fitted into the circular holes 51a, 51b, 51c, 51d, 51e of the carriers 52a, 52b, 52c, 52d, 52e, and thereafter the carriers 52a, 52b, 52c, 52d, 52e are sandwiched between the pair of the upper and lower platens 54a, 54b having the pads 53a, 53b, and then the center gear 56 is rotated to conduct the sun-and-planet motion of the carriers 52a, 52b, 52c, 52d, 52e along the guide 55 while supplying free abrasive grains to the wafers 57a, 57b, 57c, 57d, 57e, to thereby lap the wafers 57a, 57b, 57c, 57d, 57e.

In the lapping apparatus 50, the area occupied by the center gear 56 is large and the area of the upper and lower platens 54 becomes large accompanied therewith, and hence the whole size of the lapping apparatus 50 tends to be grown. In the lapping of the semiconductor wafers having a diameter of not less than 450 mm, the sizes of the carriers 52a, 52b, 52c, 52d, 52e are grown and hence the force required for the sun-and-planet motion of the carriers 52a, 52b, 52c, 52d, 52e becomes large to grow the size of the center gear 56, and as a result, the size of the lapping apparatus 50 becomes larger, which is a serious problem. In FIG. 3, when the diameter of the platen 54 is L2, if three semiconductor wafers of 450 mm in diameter are lapped, L2 is about 2200 mm, which is much larger than L1 in the fixed grain bonded abrasive grinding apparatus 10. Thus, when silicon wafers having a diameter of not less than 450 mm are produced by a method including the lapping step, it is required to use a very large lapping apparatus, which may cause a problem in the installation site and the like.

Also, in the lapping step, the size of the guide becomes larger since the lapping is conducted while supplying free abrasive grains. As a result, the supply area of free abrasive grains becomes wider with respect to silicon wafers having a diameter of not less than 450 mm, and it is difficult to supply them uniformly, which may easily deteriorate the flatness of the semiconductor wafer after the lapping step but also may cause the cracking or chipping in the lapping.

(IG Heat Treating Step)

An IG (intrinsic gettering) heat treating step is conducted using a heat treating apparatus for rapid temperature rising and falling, or a single wafer type silicon wafer heating apparatus with an infrared lamp in this embodiment. This apparatus comprises halogen tungsten midget lamps, which are arranged above an upper face of the wafer so as to cover a region wider than the wafer area and controls multi-zones concentrically to heat the silicon wafer itself through irradiation and absorption of light from one side to the silicon wafer. The wafer is designed so that the peripheral portion thereof is supported by a ring-shaped heat-resistant wafer holder over a whole of the outer peripheral region to make in-plane strain as small as possible. In this apparatus, the wafer is placed at a room temperature and heated to 400° C. while purging with Ar until an oxygen concentration inside the furnace is not more than 100 ppm before the flowing of NH₃ as a nitriding gas and held at this temperature at once, and thereafter heated to a given temperature of 1200° C. at a rate of 50° C./sec while mixing with NH₃ gas and kept at this temperature for 10 seconds, and then quenched to 800° C. at a rate of 50° C./sec. At 800° C., the gas is switched to N₂, and NH₃ gas in the furnace is purged to not more than 1%, and thereafter the wafer is taken out.

(High-Temperature Defect-Shrinking and Elimination Heat-Treating Step)

In the high-temperature defect-shrinking and elimination heat-treating step, a boat provided with a silicon wafer is charged at a charging rate of 50 mm/min into a batch type heat-treating furnace kept at a temperature of 500° C. and thereafter heated at a temperature rising rate of 10° C./min up to 700° C., 5° C./min up to 800° C., 2° C./min up to 1000° C. and 1° C./min up to 1000° C.-1200° C., kept at 1200° C. for 1 hour, cooled down at a rate of 1° C./min up to 1000° C., 2° C./min up to 800° C. and 5° C./min up to 500° C., and then the boat is taken out at a rate of 50 mm/min.

(Chemical Treating Step)

The chemical treating step simultaneously conducts reduction of machining strain on the surfaces and end face of the semiconductor wafer applied at the slicing step or both the slicing step and the fixed grain bonded abrasive grinding step, and a finish beveling of making the end face of the semiconductor wafer to a given beveled form, which may be either a batch type or a single wafer type chemical treatment.

The batch type chemical treatment is a treatment of immersing a plurality of semiconductor wafers (e.g. 24 wafers) into a vessel containing a given etching solution to simultaneously conduct the reduction of machining strain on both surfaces and end faces of the semiconductor wafer and the finish beveling of making the end face of the semiconductor wafer to a given beveled form. Therefore, it is possible to shorten the number of production steps as a whole in the production method of the semiconductor wafer without separately conducting a step of beveling the end face of the semiconductor wafer.

The single wafer type chemical treating step is a treatment that one semiconductor wafer is rotated while adding dropwise an etching solution to a one-side face of the semiconductor wafer, whereby the etching solution is extended over the both surfaces and end faces of the semiconductor wafer through centrifugal force to reduce machining strain on both the surfaces and end face of the semiconductor wafer, and at the same time the end face of the semiconductor wafer is subjected to a finish beveling to a given beveled form. The single wafer type chemical treatment is subjected twice to each one-side face before and after the following one-side finish polishing so that both surfaces of the semiconductor wafer are etched. On the end face, conditions of etching are set for making a given form by two etching.

As the etching solution, it is preferable to use a mixed acids of hydrofluoric acid, nitric acid and phosphoric acid, because it is required that when the etching solution is added dropwise to the rotating semiconductor wafer, it is extended over the surface of the semiconductor wafer to be etched at a proper rate to form a uniform film of the etching solution on this surface. A mixed acid of hydrofluoric acid, nitric acid and acetic acid usually used as the etching solution in the immersion etching is not preferable because it is low in the viscosity and when it is added dropwise to the rotating semiconductor wafer, a rate of extending over the surface to be etched is too fast and the film of the etching solution is not formed, resulting in irregular etching.

Moreover, the mixed acid of hydrofluoric acid, nitric acid and phosphoric acid used as the etching solution in the single wafer type chemical treatment is preferable to comprise 5˜20% of hydrofluoric acid, 5˜40% of nitric acid, 30˜40% of phosphoric acid by mass.

(One-Side Finish Polishing Step)

In the one-side finish polishing step, a surface of the single wafer type etched semiconductor wafer is polished with a polishing cloth made of urethane or the like while supplying a polishing slurry. The kind of the polishing slurry is not particularly limited, but colloidal silica having a particle size of not more than 0.5 μm is preferable.

The one-side finish polishing step is conducted twice before and after the single wafer type etching, and a surface of the second one-side finish polished semiconductor wafer finally becomes a device surface.

Although the above is described with respect to the main steps in the production method according to the invention, a polishing step of beveled portion and/or an epitaxial layer growing step may be included, if desired. The polishing step of beveled portion and the epitaxial layer growing step will be described below.

(Polishing Step of Beveled Portion)

The polishing step of the beveled portion is conducted after the second single wafer type etching step for polishing the beveled portion of the semiconductor wafer to reduce a variation of the beveled width in the wafer. In this case, the beveled portion is polished with an abrasive cloth made of urethane or the like while supplying an abrasive slurry. The kind of the abrasive slurry is not particularly limited, but colloidal silica having a particle size of about 0.5 μm is preferable.

(Epitaxial Layer Growing Step)

A semiconductor wafer having an epitaxial layer can be obtained by conducting the epitaxial layer growing step after the chemical treating step or the one-side finish polishing step. When the epitaxial layer is grown on the surface of the semiconductor wafer, it is required to remove surface damage of the semiconductor wafer applied at the slicing step and optionally at the fixed grain bonded abrasive grinding step, so that the epitaxial layer growing step is preferable to be conducted after the chemical treating step or the one-side finish polishing step.

Although the above is merely described with respect to one embodiment of the invention, various modifications may be made without departing from the scope of the appended claims.

A semiconductor wafer is prepared by the production method according to the invention as stated below.

### Example 1

A sample silicon wafer having a diameter of 300 mm is prepared according to the process flow of an embodiment of the invention shown in FIG. 1.

### Example 2

A sample silicon wafer is prepared by the same production method as in Example 1 except that the diameter of the silicon wafer is 450 mm.

### Comparative Example 1

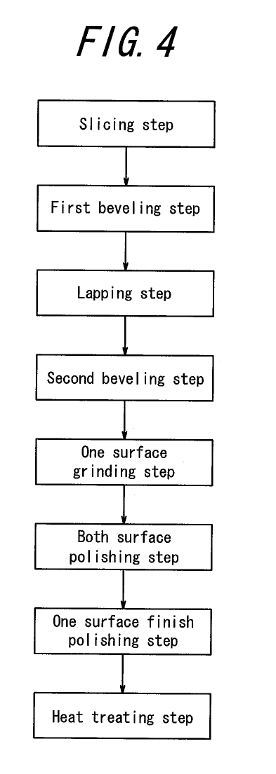

A sample silicon wafer having a diameter of 300 mm is prepared by the conventional method of producing a semiconductor wafer including a lapping step as shown in FIG. 4.

### Comparative Example 2

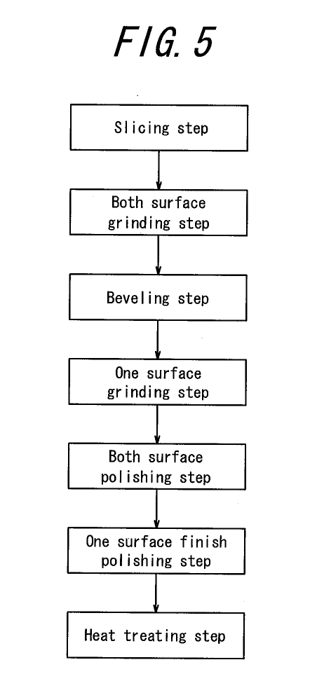

A sample silicon wafer having a diameter of 300 mm is prepared by a production method of a semiconductor wafer using a double-side grinding step shown in FIG. 5 instead of the first beveling step and lapping step shown in FIG. 4.

With respect to each of the thus obtained samples are evaluated the residual strain value in silicon, end face damage and kerf loss. The evaluation method will be described below.

(Residual Strain Value in Silicon)

In Examples 1 and 2 are measured residual strains of the semiconductor wafer before and after the second one-side finish polishing step, while residual strains of the semiconductor wafer after the heat treatment are measured in Comparative Examples 1 and 2.

(End Face Damage)

End face damages of each sample are measured using an optical auto-inspection apparatus and evaluated as follows.

◯: no damage

X: damage (fault)

The evaluation results of each sample are shown in Table 1.

TABLE 1

| | | | Comparative | Comparative |
|---|---|---|---|---|
| | Example 1 | Example 2 | Example 1 | Example 2 |
| Process flow | FIG. 1 | FIG. 1 | FIG. 4 | FIG. 5 |
| Diameter (mm) | 300 | 450 | 300 | 300 |
| Silicon wafer | 0.1 | 0.2 | 0.6 | 0.5 |
| strain SIRD- | | | | |
| GBA value | | | | |
| End face | ◯ | ◯ | X | X |
| damage in edge | | | | |
| Machining | 45 | 60 | 100 | 105 |
| allowance of | | | | |
| silicon material | | | | |
| (Kerf loss) (μm) | | | | |

As seen from the above table, Example 1 shows a minimum value on the residual strain in silicon, is good for the end face damage in edge end face and shows a kerf loss of 45 μm. Example 2 shows good results substantially equal to those of Example 1. From these results, it is confirmed that a large-size silicon wafer being less in the residual strain in silicon and no end face damage in edge and small in the kerf loss and having a high quality and a diameter of 450 mm is obtained by the production method according to the first embodiment of the invention.

On the other hand, Comparative Examples 1 and 2 are large in the residual strains in silicon, poor in the end face damage in edge end face and have a large kerf loss of not less than 100 μm as compared with Examples 1 and 2.

With the foregoing in mind, it is an object of the invention to provide a production method, in which the beveling step conducted for preventing the cracking or chipping in a raw wafer during the grinding can be omitted when the raw wafer cut out from a crystalline ingot is processed into a double-side mirror-finished semiconductor wafer and the semiconductor wafer can be obtained cheaply by reducing the production step number for the semiconductor wafer and further decreasing the machining allowance of silicon material in the semiconductor wafer to reduce the kerf loss of the semiconductor material.

Particularly, the invention exerts a remarkable effect when the semiconductor wafer is a large-size silicon wafer having a diameter of not less than 450 mm.

1. A method of producing a semiconductor wafer, which comprises:
a slicing step of cutting out a thin disc-shaped raw wafer from a crystalline ingot;
a fixed grain bonded abrasive grinding step of sandwiching the raw wafer between a pair of upper and lower platens each having a pad of fixed grain bonded abrasive to simultaneously grind both surfaces of the raw wafer;
a heat treating step of subjecting the raw wafer to a given heat treatment after the fixed grain bonded abrasive grinding step; and
a one-side polishing step of polishing each of the both surfaces of the raw wafer after the heat treating step.

2. A method of producing a semiconductor wafer, which comprises:
a slicing step of cutting out a thin disc-shaped raw wafer from a crystalline ingot;
a fixed grain bonded abrasive grinding step wherein the raw wafer is fitted into a circular hole of a carrier having a plurality of circular holes closely aligned to each other and thereafter the carrier is sandwiched between a pair of upper and lower platens each having a pad of fixed grain bonded abrasive and then the upper and lower platens are rotated while oscillating the carrier in the same horizontal plane to simultaneously conduct a high-speed treatment from rough grinding to finish grinding on both surfaces of the raw wafer at once;
a heat treating step of subjecting the raw wafer worked at the high speed in the fixed grain bonded abrasive grinding step to a given heat treatment;
a chemical treating step of simultaneously conducting mitigation of machining strains from the surfaces and end face of the raw wafer subjected to the heat treatment and finish beveling of the end face of the raw wafer into a given beveled shape; and
a one-side finish polishing step of finish-polishing the surface of the chemical-treated raw wafer.

3. A method of producing a semiconductor wafer according to claim 1, wherein the given heat treatment includes a high-temperature defect-shrinking and elimination heat treatment for vanishing defects from a surface layer of the raw wafer at a higher temperature and/or an IG heat treatment for forming a gettering layer or a vacancy injected layer as a nucleus thereof in an interior of the raw wafer other than the surface layer thereof.

4. A method of producing a semiconductor wafer according to claim 3, wherein the IG heat treatment includes a heat treatment at a middle temperature range of 700 to 900° C. for not less than 30 minutes for forming precipitation nuclei or a heat treatment in a high-temperature nitriding atmosphere of not lower than 1150° C. for vacancy injection.

5. A method of producing a semiconductor wafer according to claim 3, wherein the high-temperature defect-shrinking and elimination heat treatment includes a heat treatment in an atmosphere of a reducing gas, an inert gas or a mixed gas thereof at 1100 to 1350° C. for not less than 1 minute.

6. A method of producing a semiconductor wafer according to claim 1, wherein the semiconductor wafer is a large-size silicon wafer having a diameter of not less than 450 mm.

7. A method of producing a semiconductor wafer according to claim 2, wherein the given heat treatment includes a high-temperature defect-shrinking and elimination heat treatment for vanishing defects from a surface layer of the raw wafer at a higher temperature and/or an IG heat treatment for forming a gettering layer or a vacancy injected layer as a nucleus thereof in an interior of the raw wafer other than the surface layer thereof.

8. A method of producing a semiconductor wafer according to claim 4, wherein the high-temperature defect-shrinking and elimination heat treatment includes a heat treatment in an atmosphere of a reducing gas, an inert gas or a mixed gas thereof at 1100 to 1350° C. for not less than 1 minute.

9. A method of producing a semiconductor wafer according to claim 2, wherein the semiconductor wafer is a large-size silicon wafer having a diameter of not less than 450 mm.

10. A method of producing a semiconductor wafer according to claim 3, wherein the semiconductor wafer is a large-size silicon wafer having a diameter of not less than 450 mm.

11. A method of producing a semiconductor wafer according to claim 4, wherein the semiconductor wafer is a large-size silicon wafer having a diameter of not less than 450 mm.

12. A method of producing a semiconductor wafer according to claim 5, wherein the semiconductor wafer is a large-size silicon wafer having a diameter of not less than 450 mm.
